(19) United States
(12) Patent Application Publication
(10) Pub. No.: US 2007/0184671 A1
(43) Pub. Date: Aug. 9, 2007

(54) Method for production of group lll nitride semiconductor device

(75) Inventors: Takaki Yasuda, Chiba (JP); Mineo Okuyama, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K.

(21) Appl. No.: 10/558,668

(22) PCT Filed: May 28, 2004
(86) PCT No.: PCT/JP04/07769

§ 371 Date: Dec. 18, 2006

Related U.S. Application Data
(60) Provisional application No. 60/475,788, filed on Jun. 5, 2003.

(30) Foreign Application Priority Data
May 30, 2003 (JP) 2003-153756

(51) Int. Cl. H01L 21/31

(52) U.S. Cl. 438/790

(57) ABSTRACT

A method for producing a Group III nitride semiconductor device includes forming on a substrate or a surface of a Group III nitride semiconductor crystal a mask of a SiO₂ or SiNₓ film partially covering the substrate or the surface of the Group III nitride semiconductor crystal and subsequently forming a Group III nitride semiconductor. The SiO₂ film is formed by the radical shower CVD technique. The SiNₓ film is formed by the catalytic CVD technique.

### CROSS REFERENCE TO RELATED APPLICATIONS

This application is an application filed under 35 U.S.C. §111(a) claiming the benefit pursuant to 35 U.S.C. § 119(e)(1) of the filing date of Provisional Application No. 60/475,788 filed Jun. 5, 2003 pursuant to 35 U.S.C. § 111(b).

### TECHNICAL FIELD

This invention relates to a method for the production of a high-output light-emitting diode (LED). More particularly, the invention relates to a method for the production of a group III nitride semiconductor (represented by InGaAlN, for example) light-emitting diode (LED).

### BACKGROUND ART

The Group III nitride semiconductor forms a high-output LED from the near ultraviolet region through the blue color region because it possesses a bandgap of the direct transition type of energy corresponding to the visible radiation through the ultraviolet region and permits highly efficient emission. The white light LED that is formed by adding a fluorescent material to the high-output LED has been already materialized. The desirability of developing an LED of higher output and higher efficiency for use in illumination has been finding growing recognition.

The light emitting efficiencies of the LEDs are mainly divided into the “internal quantum efficiency” which is the efficiency of conversion from an injected-electron and positive-hole pair into a photon and the “light extraction efficiency” which is the efficiency with which a generated photon is extracted into the air. The LEDs of the near ultraviolet region through the blue color region that are formed of the conventional Group III nitride semiconductors have been mainly directed toward concentrating the internal quantum efficiency.

As one outcome of the study on the light extracting efficiency performed concerning the LEDs of the near ultraviolet region through the blue color region that are formed of Group III nitride semiconductors, a light emitting device using a sapphire patterned substrate has been disclosed in Japanese Journal of Applied Physics, Vol. 41 (2002) pp. L1431-L1433, for example. For the formation of the patterned structure of the substrate, a procedure which comprises coating the entire surface of a given substrate with a film of silicon oxide (SiO₂) or silicon nitride (SiNₓ), forming a selective etching mask finished with openings by using the photolithographic technique, and partly etching the opening parts of the substrate and the Group III nitride semiconductor crystal by the reactive ion etching (RIE) technique is utilized. For the formation of the film of SiO₂ or SiNₓ, the plasma CVD technique is widely adopted.

As an example of the procedure which comprises forming a selective growth mask of SiO₂ or SiNₓ furnished with openings on the surface of a Group III nitride semiconductor crystal and effecting selective growth of the Group III nitride semiconductor crystal, an invention aimed at manufacturing a current constriction structure for use in a laser diode has been disclosed in JP-A HEI 10-190142 and an invention aimed at reducing the threading dislocation density has been disclosed in JP-A HEI 11-31864.

Then, as an example of the prior art of forming a selective growth mask of SiO₂ or SiNₓ containing openings on the surface of a substrate and effecting selective growth of a Group III nitride semiconductor crystal, an invention directed toward forming a mask on a sapphire substrate has been disclosed in JP-A HEI 11-31864.

The present inventors have found that during the formation of a selective etching mask or selective growth mask of SiO₂ or SiNₓ by the plasma CVD technique, on a substrate or Group III nitride semiconductor crystal, damage is inflicted on the surface of the substrate or Group III nitride semiconductor crystal to the extent of impairing the property and the yield.

To be specific, firstly during the execution of dry etching for exposing an n-type contact layer, the protective film of SiO₂ or SiNₓ is formed in advance in the part of the p-type contact layer that is not to be etched. The conventional plasma CVD technique adopted for this dry etching has entailed such problems as inflicting damage to the p-type contact layer during the formation of the protective film, impairing the contact resistance of the p-type contact layer and preventing the forward voltage from being lowered as expected.

Secondly in the formation of an insulating protective film of SiO₂ or SiNₓ between a p-type electrode and an n-type electrode or on the entire area of a device, the conventional plasma CVD technique adopted for this formation has been at a disadvantage in inducing direct collision of an accelerated plasma ion species against the edge portions of the electrodes, the surfaces of contact layers and the side faces of the p-type layer, n-type layer and emission layer, inflicting damage on the parts exposed to the collision and preventing the low current region during the application of forward voltage or the leak current during the application of backward voltage from being lowered as expected.

Thirdly during the execution of the procedure generally called an epitaxial lateral overgrowth (ELO) technique which comprises forming a selective growth mask of SiO₂ or SiNₓ on the surface of a substrate or Group III nitride semiconductor and growing a Group III nitride semiconductor crystal on the selective growth mask, the conventional plasma CVD technique adopted for the procedure has entailed the problem of revealing deficiency of yield. After the selective growth mask is formed of SiO₂ or SiNₓ on the entire surface of a given sample by the plasma CVD technique, the SiO₂ film or the SiNₓ film is removed from the parts in which it is expected that the Group III nitride semiconductor crystal be grown. When the sample is examined by the X-ray diffraction technique, the exposed surface of the substrate or the exposed surface of the Group III nitride semiconductor crystal reveals disturbance of the atomic arrangement and the Group III nitride semiconductor crystal nuclei grown on the exposed surface reveal deviation of mutual crystal orientations. As a result, when the crystal nuclei mutually coalesce to flatten the entire surface, the mutual orientations or crystal faces fail to unify, give rise to steps in the formed surface and leave the pits unfilled, with the result that the manufactured LED will exhibit no diode properties.

This disadvantage may be logically explained by a supposition that the electrically charged atoms, molecules, etc. (ion species) in the accelerated plasma gas collide against the substrate during the formation of the mask and consequently inflict damage on the regrown surface.

This invention is aimed at providing the operation of forming a film of SiO₂ or SiNₓ on a substrate or Group III nitride semiconductor crystal by the CVD technique with a method for producing the substrate coated with the film without inflicting damage on the surface of the substrate or the surface of the Group III nitride semiconductor crystal.

### DISCLOSURE OF THE INVENTION

The method contemplated by this invention for producing a Group III nitride semiconductor device comprises forming on a substrate a mask of a SiO₂ film partially covering the substrate and subsequently forming a Group III nitride semiconductor, wherein the SiO₂ film is formed by the radical shower CVD technique.

Then, the method contemplated by this invention for producing a Group III nitride semiconductor device comprises forming on the surface of a Group III nitride semiconductor crystal a mask of a SiO₂ film partially covering the surface of the Group III nitride semiconductor crystal and subsequently forming a Group III nitride semiconductor, wherein the SiO₂ film is formed by the radical shower CVD technique.

In each of the methods described above, the radical shower CVD technique comprises introducing a plasma gas onto the substrate or the surface of the Group III nitride semiconductor crystal via a partitioning plate that lowers plus and minus electric charges in the plasma.

In each of the methods described above, the substrate is formed of one member selected from the group consisting of sapphire, SiC, gallium nitride and aluminum nitride.

In each of the methods, the SiO₂ mask has a structure having a multiplicity of stripes arranged along a (11-20) or (1-100) direction of a crystal of the substrate or the group III nitride semiconductor crystal.

In each of the methods described above, the SiO₂ mask has a structure having a multiplicity of hexagons arranged along a (11-20) or (1-100) direction of a crystal of the substrate or the group III nitride semiconductor crystal.

Further, the method contemplated by this invention for producing a Group III nitride semiconductor device comprises forming on a substrate a mask of a SiNₓ film partly covering the substrate and subsequently forming a Group III nitride semiconductor, wherein the SiNₓ film is formed by the catalytic CVD technique.

Then, the method contemplated by this invention for producing a Group III nitride semiconductor device comprises forming on the surface of a Group III nitride semiconductor crystal a mask of a SiNₓ film partly covering the surface of the Group III nitride semiconductor crystal and subsequently forming a Group III nitride semiconductor, wherein the SiNₓ film is formed by the catalytic CVD technique.

In the methods just described above, the catalytic CVD technique comprises contacting a SiNₓ raw material gas with a hot heating member to be decomposed and introduced onto a surface of the substrate or Group III nitride semiconductor crystal.

In the method just described above, the hot heating member is formed of tungsten.

In the methods described above, the substrate is formed of one member selected from the group consisting of sapphire, SiC, gallium nitride and aluminum nitride.

In the methods described above, the SiNₓ mask has a structure having a multiplicity of stripes arranged along a (11-20) or (1-100) direction of a crystal of the substrate or the Group III nitride semiconductor crystal.

In the methods described above, the SiNₓ mask has a structure having a multiplicity of hexagons arranged along a (11-20) or (1-100) direction of a crystal of the substrate or the Group III nitride semiconductor crystal.

By forming the mask partially covering the surface of a semiconductor substrate or semiconductor crystal, with a SiO₂ film produced by the radical shower CVD technique or with a SiNₓ film produced by the catalytic CVD technique as described above, this invention is enabled to abate the damage inflicted on the surface of the semiconductor substrate or semiconductor crystal, heighten the yield and permit production of a Group III nitride semiconductor with high yield.

### BRIEF DESCRIPTION OF THE DRAWING

FIG. 1 is a schematic cross section illustrating one example of the CVD device for executing a radical shower CVD technique.

FIG. 2 is a schematic cross section illustrating one example of the CVD device for executing a catalytic CVD technique.

FIG. 3 is a schematic view illustrating one example of the cross section of an epitaxial wafer possessing an epitaxial layer structure for use in a semiconductor light-emitting device of this invention.

### BEST MODE OF EMBODYING THE INVENTION

This invention, in the production of a semiconductor device by forming a mask partially covering the surface of a semiconductor substrate or semiconductor crystal and subsequently forming a Group III nitride semiconductor, concerns a method for producing a Group III nitride semiconductor which comprises forming the mask with a SiO₂ film by the radical shower CVD technique or with a SiNₓ film by the catalytic CVD technique.

In the method for producing the Group III nitride semiconductor device according to this invention, the case of forming the mask partially covering the surface of the substrate or semiconductor with a SiO₂ film obtained by the radical shower CVD technique will be described. The radical shower CVD technique is a CVD technique that discriminates between a plasma region and a film-forming region and refrains from inflicting plasma damage on the substrate or Group III nitride semiconductor crystal. Since the life of the neutral radical of an element required to form the film varies from one element to another, this technique is effective for an element that has a life long enough to reach the substrate. The radical shower CVD technique is effective for oxygen because the neutral radical of oxygen has a long life. It is inferred to induce the following reaction with oxygen SiH₄+O*→H₃SiO→H₂SiO→SiO to form SiO₂ on the surface of a substrate.

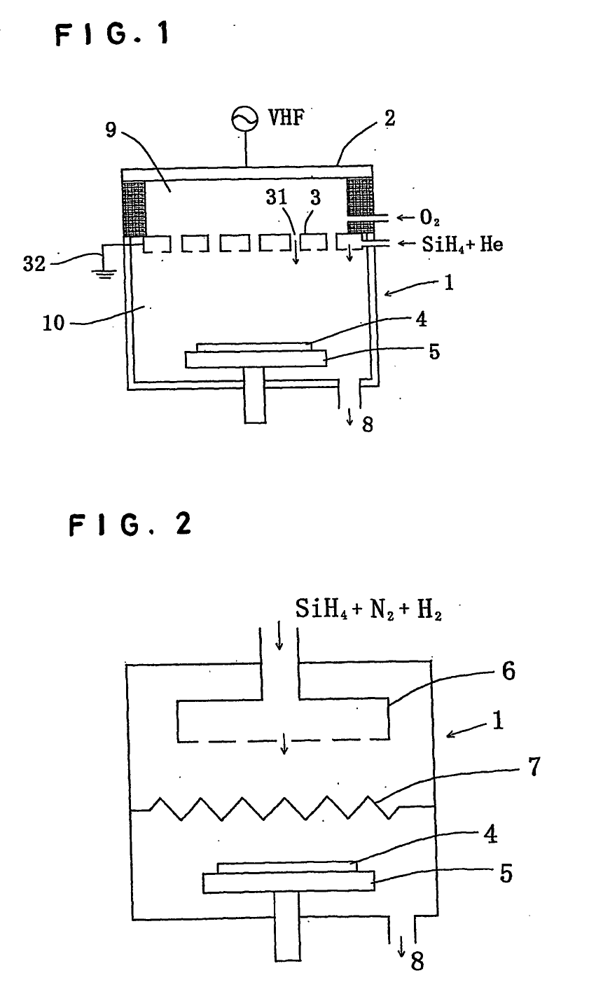

This radical shower CVD technique (hereinafter referred to as “RS-CVD”) will be described below with reference to FIG. 1. A CVD device 1 is divided with a partitioning plate 3 into a plasma region 9 and a film-forming region 10. When a plasma gas contacts the partitioning plate 3, an ion species bearing a plus or minus electric charge in the plasma region 9 is transformed into a neutral atom or molecule, such as a radical, and this radical is admitted into the film-forming region 10 and introduced onto a substrate 4. For the sake of this introduction onto the substrate, the pressure P1 of the plasma region and the pressure P2 of the film-forming region are retained in the relation of P1>P2. The method of separating the plasma region possessing an electric charge and the film-forming region possessing a lowered electric charge as described above in the CVD technique is referred to by this invention as an RS-CVD technique. The partitioning plate is only required to be capable of rendering the electric charge in the plasma neutral. The device that is illustrated in FIG. 1 uses, as one example, an electroconductive partitioning plate that is made of a metallic material and grounded 32. The plasma region is formed of an electrode 2 using a very high frequency (VHF) power source and is supplied therein with oxygen gas. The partitioning plate that has a hollow build admits SiH₄ gas and He gas supplied thereto and delivers them therefrom to the film-forming region. The plasma gas, on contacting the partitioning plate 3, has the electric charge thereof neutralized and the plus or minus ion species is consequently reduced and induced to enter the film-forming region 5 via venting holes 31 in the partitioning plate. A SiO₂ film is consequently formed on the substrate 4. In FIG. 1, denoted by 5 is a substrate support and by 8 is a gas exhaust port.

In the method for the production of the Group III nitride semiconductor device according to this invention, when the mask partially covering the surface of the substrate or semiconductor crystal is a SiNₓ film, it is manufactured by the catalytic CVD technique. The catalytic CVD technique is a method that comprises decomposing a raw material gas by the use of a hot heating member, preferably a heating member serving as a decomposition catalyst for the raw material, and forming a SiNₓ film on the surface of a substrate or semiconductor crystal. Since this technique reduces the plus or minus ion species on the surface of the substrate as compared with the conventional plasma technique, it abates plasma damage and obtains a good SiNₓ film.

This catalytic CVD technique will be described below with reference to FIG. 2. In FIG. 2, the same reference numerals as used in FIG. 1 denote the same components. The raw material gases, namely SiH₄ and H₂, and the carrier gas H₂ are supplied by a raw material supply member 6 into the CVD device 1 and these gases are brought into contact with a heating member 7. The heating member 7 is preferably made of a metallic material, such as tungsten, that serves as a decomposition catalyst for the raw material gas. The heating member 7 may be in the form of a net produced by interlacing wires made of a given metallic material. It may be otherwise in the form of a bed produced by amassing granules of a given metallic material and endowed with air permeability.

According to the radical shower CVD technique and the catalytic CVD technique mentioned above, the scarcity of atoms possessing ions on the surface of the substrate has been ascertained by the method of plasma spectroscopy. By the plate probing method, it has been ascertained that the plasma ion density in the film-forming chamber of the radical shower CVD technique falls in the range of 10² to 10³ cm⁻³ that is a magnitude seven places of decimals lower than the magnitude 10⁸ to 10¹⁰ cm⁻³ that prevails in the conventional parallel plate plasma CVD.

The RS-CVD technique and the catalytic CVD technique according to this invention avoid appreciably impairing the atomic arrangement and the surface flatness on the surface of the substrate or the surface of the Group III nitride semiconductor crystal exposed by etching as compared with the conventional CVD technique. As regards the GaN film surface from which the SiO₂ film formed by the RS-CVD technique or the SiNₓ film formed by the catalytic CVD technique has been removed, it has been clearly observed by the AFM that the appearance of the step flow of the GaN film surface is as smooth as before the formation of the SiO₂ film or SiNₓ film. In the case of the conventional CVD technique, the GaN film surface from which the SiO₂ film or SiNₓ film has been removed is found to describe a step flow line which is not smooth but in a finely pleated state. The neighborhood around the core of transfer is copiously etched and is clearly observed as a pit. According to the ZC image in the cross section TEM, the GaN film in the neighborhood of the interface forming the SiO₂ film or SiNₓ film shows a clear difference between the GaN film formed by the RS-CVD technique or catalytic CVD technique and the GaN film formed by the conventional CVD technique. In the case of the conventional technique, the GaN film in the neighborhood of the interface appears to be white as compared with the GaN film in the remote part from the interface. This fact indicates that the lattice arrangement or the crystal orientation is disturbed in the neighborhood of the interface. On the sample formed by the RS-CVD technique or catalytic CVD technique, no difference in contrast is recognized between the GaN film in the neighborhood of the interface and the GaN film at a portion remote from the interface. The preceding effects have resulted in solving the following problems.

Firstly, the dry etching performed for exposing the n-type contact layer avoids inflicting any damage on the p-type contact layer, exalts the contact resistance of the p-type contact layer and shows an effect in reducing the forward voltage.

Secondly, during the formation of an insulating protective film covering the interval between the p-type electrode and the n-type electrode or the entire device, no damage is inflicted on the edge portions of the electrodes, the surfaces of the contact layers and the side faces of the p-type layer, n-type layer and emission layer, and the low current region during the application of the forward voltage and the leak current during the application of the backward voltage are improved.

Thirdly, during the execution of the ELO technique, the coalescence of crystal nuclei is improved, the entire surface of a 2-inch wafer is flattened, and the quality and the yield of the manufactured LED are greatly improved.

Generally, the method of this invention for the production of a Group III nitride semiconductor device according to the radical shower CVD technique or the catalytic CVD technique excels in quality and yield as compared with the method for the production of a Group III nitride semiconductor device using the conventional CVD technique.

In this invention, it is commendable to form on the surface of the SiO₂ film formed by the radical shower CVD technique or the surface of the SiNₓ film formed by the catalytic CVD a resist film patterned by the photolithographic technique and partially expose the substrate or the Group III nitride semiconductor crystal by the use of a hydrofluoric acid.

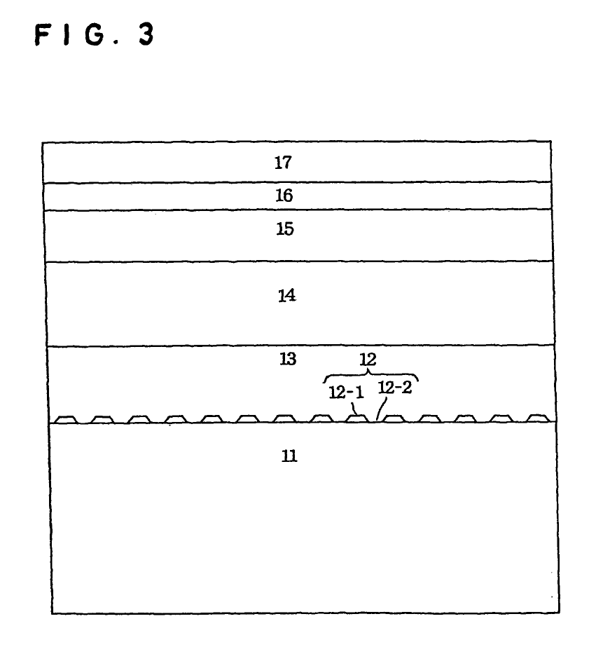

The method for forming a partial mask with SiO₂ and SiNₓ in this invention resorting to a SiO₂ film is preferred to adopt a structure having a multiplicity of stripes or hexagons of mask arranged at stated intervals along the (11-20) direction or the (1-100) direction of a group III nitride semiconductor crystal. The expression “the mask is formed along the (11-20) direction or the (1-100) direction” as used in this description shall be construed as embracing the case of having the direction deviate within the range of ±5°. As respects the structure of stripes, linear stripes 12-1 form a mask 12 and their intervals form spaces 12-2 as illustrated in FIG. 3 and these are extended in directions perpendicular to the page surface.

In this invention, glass, Si, GaAs and GaP as well as sapphire, GaN, AlN and SiC are available as the substrate.

For the plane direction of the hexagonal substrate, the m plane, a plane, c plane, etc. are usable. Among the planes enumerated above, the c plane ((0001) plane) proves particularly favorable. Further, the perpendicular axis of the surface of the substrate is preferably inclined in a specific direction from the <0001> direction. The substrate to be used in this invention is preferred to undergo a pretreatment, such as organic cleaning or etching because this pretreatment enables the surface of the substrate to be retained in a fixed state.

In the production of the light emitting device of this invention, relevant methods hitherto known may be used for the growth of the n-type layer, p-type layer, emission layer, etc., the formation of electrodes, and the inclusion of resin. For the growth of a semiconductor, the method of metal organic chemical vapor deposition (MOCVD), the method of vapor phase epitaxy (VPE) and the method of molecular beam epitaxy (MBE) are usable as means for vapor phase growth

Now, this invention will be described specifically below as based on examples.

### EXAMPLE 1

A sapphire substrate having a (0001) plane on the front face and measuring 2 inches in diameter was used in Example 1. After this sapphire substrate was degreased with an organic solvent and cleaned with an acid, a SiO₂ film was formed on the entire surface of the sapphire substrate in a thickness of 80 nm by the radical shower CVD technique illustrated in FIG. 1.

Thereafter, a resist film was applied to the entire surface by means of spin coating and dried. A photo-mask of a stripe structure of 2 μm×2 μm line & space was fixed as aligned with the <1-100> direction of the sapphire substrate. The resist film was partially exposed to light with an exposure device and the exposed part of the resist film was washed out. Then, the part of the SiO₂ film no longer covered with the resist film was removed with hydrofluoric acid to expose the sapphire substrate. The side faces of SiO₂ film were intentionally inclined through adjustment of the etching conditions. The finally remaining resist was removed. Consequently, a selectively grown mask of SiO₂ in the stripe structure of 2 μm×2 μm illustrated in FIG. 3 was formed.

The sapphire substrate consequently manufactured as covered with the selectively grown mask of SiO₂ was degreased with an organic solvent and cleaned with an acid and then introduced into a MOCVD device. In the device, it was heated to 1160° C. and retained thence at this temperature constantly. This sapphire substrate as a first step was swept with a gas containing a vapor of trimethyl aluminum (TMAl) to coat the substrate with Al grains or an Al film. As a second step, the coated substrate was swept with ammonia till thorough conversion of the Al grains or Al film into aluminum nitride. Subsequently as a third step, the substrate now coated with aluminum nitride was swept with trimethyl gallium (TMGa) and ammonia to form a non-doped gallium nitride (GaN) crystal layer over a period of three hours. The GaN surface after the three hours' growth was flat.

Subsequently, at the following steps, an n-type layer, an emission layer and a p-type layer were sequentially superposed in the order mentioned to manufacture an epitaxial wafer or LEDs.

While TMGa and NH₃ were continuously supplied to the non-doped GaN crystal layer, supply of SiH₄ thereto was started to induce growth of a Si-doped n-type GaN layer over a period of about one hour and 15 minutes. The amount of the SiH₄ so supplied was adjusted to give an electron concentration of 1×10¹⁹ cm⁻³ to the Si-doped GaN layer. The thickness of the Si-doped GaN layer was 2 μm.

After the Si-doped GaN layer was grown, the valves for TMGa and SiH₄ were switched to stop the supply of these raw materials to the furnace. While the flow of ammonia was continued, the valve for the carrier gas was switched to start supply of nitrogen in the place of hydrogen. The temperature of the substrate was subsequently lowered from 1160° C. to 830° C.

During the suspension of the growth resulting from the change of temperature, the flow of the carrier gas of trimethyl indium (TMIn) and triethyl gallium (TEGa) to a bubbler was started. The vapors of TMIn and TEGa generated by the bubbling were advanced together with the carrier gas to the pipe of a removal device and discharged via the removal device to the exterior of the system till the step for the growth of the clad layer was started.

Next, an emission layer in a multiple quantum well structure formed of a barrier layer of GaN and a well layer of In_{0.06}Ga_{0.94}N was manufactured. The manufacture of the multiple quantum well structure was effected by first forming a GaN barrier layer 7 nm in thickness and forming thereon an In_{0.06}Ga_{0.94}N well layer 3 nm in thickness. After this structure was superposed up to five layers, a sixth GaN barrier layer was formed on the fifth In_{0.06}Ga_{0.94}N well layer to obtain a structure having the opposite sides of a multiple quantum well structure formed each of a GaN barrier layer.

On this multiple quantum well structure, a non-doped Al_{0.2}Ga_{0.8}N clad layer having a thickness of 3 mn was manufactured, with the temperature of the substrate elevated to 1100° C. and the carrier gas changed to hydrogen.

Further, on this non-doped Al_{0.2}Ga_{0.8}N clad layer, a p-type contact layer of a Mg-doped GaN was manufactured in a thickness of 0.1 μm. Cp₂Mg was used as the raw material for Mg. The amount of the Cp₂Mg to be supplied was adjusted so as to give a positive-hole concentration of 1×10¹⁸ cm⁻³ to the p-type GaN layer.

After the growth of the Mg-doped GaN layer was completed, the supply of electric current to an induction heater was stopped and the temperature of the substrate was allowed to fall to room temperature over a period of 20 minutes. During the fall of temperature from the growth temperature to 300° C., the carrier gas in the reaction furnace was formed solely of nitrogen to advance 1% by volume of NH₃. At the point of time at which the arrival of the substrate temperature at 300° C. was confirmed, the flow of NH₃ was stopped so as to form the ambient gas solely of nitrogen. After the fall of the substrate temperature to room temperature was confirmed, the wafer was extracted into the ambient air.

By the procedure described above, an epitaxial wafer having an epitaxial layer structure for a semiconductor light-emitting device was manufactured. Here, the Mg-doped GaN layer manifested a p-type performance without undergoing an annealing treatment for activation of a p-type carrier. The semiconductor light-emitting device manufactured as described above is shown in FIG. 3.

Subsequently, a light-emitting diode, i.e. one kind of the semiconductor light-emitting device, was manufactured by using the epitaxial wafer having epitaxial layer structures superposed on the sapphire substrate. On the surface of the Mg-doped GaN layer of the wafer so produced, a p-side electrode was manufactured by forming a p-electrode bonding pad of a structure having titanium, aluminum and gold superposed sequentially from the surface side and a transparent p-electrode formed solely of Au and joined to the bonding pad by the photolithographic technique.

Further thereafter, the wafer was subjected to dry etching to expose the part of the Si-doped GaN layer forming the n-side electrode. In the exposed part, an n-electrode formed of four layers respectively of Ni, Al, Ti and Au was manufactured.

In the wafer having the p-side and n-side electrodes formed therein as described above, the back surface of the sapphire substrate was ground to a thickness of 100 μm and then polished till a specular surface. Thereafter, the wafer was cut into a chip of the square of 350 μm. The chip was mounted, with the electrodes held on the underside, on a sub-mount and the sub-mount was connected to a lead frame to complete a light-emitting device. This device was sealed in the form of a cannonball with epoxy resin to manufacture a LED lamp.

When a forward current of 20 mA was passed through one hundred such LED lamps manufactured as described above, the mode of light-mitting wavelength was 382±1 nm, the mode of output value was 14.0±1.0 mW, and the number of LED lamps which satisfied both the modes was 92. When the remaining 8 LED lamps were analyzed, they were found as samples that suffered existence of defective epitaxial growth ascribable to particles.

### COMPARATIVE EXAMPLE 1

One hundred LED lamps were manufactured in Comparative Example 1 by following nearly the same procedure as in Example 1 while forming a SiO₂ film by the plasma CVD technique in the place of the radical shower CVD technique. When a forward current of 20 mA was passed through the 100 LED lamps, the mode of light-emitting wavelength was 382±1 nm, the mode of output value was 14.0±1.0 mW, and the number of LED lamps which satisfied both the modes was 55. When the remaining 45 LED lamps were analyzed, they were found as samples that suffered existence of defective epitaxial growth ascribable to particles and samples that suffered induction of current leak due to the persistence of hexagonal pits in the part of coalescence of GaN film on the SiO₂ mask.

### EXAMPLE 2

Example 2 equaled in process with Example 1 excepting the formation of SiNₓ film by the catalytic CVD technique illustrated in FIG. 2 in the place of the radical shower CVD technique. A tungsten wire net was used as the heating member in the catalytic CVD technique. When a forward current of 20 mA was passed through one hundred LED lamps manufactured herein, the mode of light-emitting wavelength was 382±1 nm, the mode of output value was 14.0±1.0 mW, and the number of LED lamps which satisfied both the modes was 96. When the remaining 4 LED lamps were analyzed, they were found as samples that suffered existence of defective epitaxial growth ascribable to particles.

### INDUSTRIAL APPLICABILITY

When the Group III nitride semiconductor crystal and the method for production of the Group III nitride semiconductor crystal according to this invention are used, since the damage inflicted on the substrate and the Group III nitride semiconductor crystal during the formation of a SiO₂ film and during the formation of a SiNₓ film can be abated, the flattening of the GaN layer during the selective growth can be promoted and consequently the yield of the Group III nitride semiconductor crystal device can be exalted conspicuously.

1-13. (canceled)

14. A method for producing a Group III nitride semiconductor device, comprising the steps of:
stacking on a substrate an n-type layer, a light-emitting layer and a p-type layer in this order, said layers constituting a Group III nitride semiconductor layer;
dry-etching the Group III nitride semiconductor layer to expose the n-type layer as a contact layer; and
using as a mask for a portion of the Group III nitride semiconductor not to be exposed an SiO₂ film formed by a radical shower CVD method during the step of dry etching.

15. A method for producing a Group III nitride semiconductor device, comprising the steps of:
stacking on a substrate an n-type layer, a light-emitting layer and a p-type layer in this order, said layers constituting a Group III nitride semiconductor layer;
dry-etching the Group III nitride semiconductor layer to expose the n-type layer as a contact layer;
providing the n-type layer and the p-type layer with an n-type electrode and a p-type electrode, respectively; and
using as a protective film covering a portion of the device between the n-type and p-type electrodes or an entire portion of the device an SiO₂ film formed by a radical shower CVD method.

16. A method for producing a Group III nitride semiconductor device, comprising the steps of:
forming on a substrate a mask formed of a SiNₓ by a catalytic CVD technique, which film partly covers the substrate; and
forming a Group III nitride semiconductor on the substrate.

17. A method for producing a Group III nitride semiconductor device, comprising the steps of:
forming on a surface of a Group III nitride semiconductor crystal a mask formed of a SiNₓ film by a catalytic CVD technique, which film partly covers the surface of the Group III nitride semiconductor crystal; and
forming a Group III nitride semiconductor on the surface of the Group III nitride semiconductor crystal.
